(19) United States
(12) Patent Application Publication
(10) Pub. No.: US 2026/0135535 A1
(43) Pub. Date: May 14, 2026

(54) MULTILAYER BANDPASS FILTER

(71) Applicant: Murata Manufacturing Co., Ltd., Nagaokakyo-shi (JP)

(72) Inventors: Yosuke MATSUSHITA, Nagaokakyo-shi (JP); Makoto OGATA, Nagaokakyo-shi (JP)

(73) Assignee: Murata Manufacturing Co., Ltd., Nagaokakyo-shi (JP)

(21) Appl. No.: 19/437,413

(22) Filed: Dec. 31, 2025

Related U.S. Application Data
(63) Continuation of application No. PCT/JP2024/017753, filed on May 14, 2024.

(30) Foreign Application Priority Data
Aug. 28, 2023 (JP) 2023-138255

(51) Int. Cl. H03H 1/00; H03H 7/01

(52) U.S. Cl. CPC H03H 1/00; H03H 7/0161; H03H 2001/0085

(57) ABSTRACT

A multilayer bandpass filter includes an LC resonator inside a multilayer body of stacked dielectric layers. The LC resonator has a loop shape arranged such that a winding axis is perpendicular to a stacking direction of the multilayer body. The LC resonator includes a capacitor conductor pattern, a line conductor pattern and a GND conductor pattern connected by first and second interlayer connecting conductors extending in the stacking direction. A capacitance portion is formed where at least a part of the capacitor conductor pattern and at least a part of the GND conductor pattern face each other on different layers. A length of the first interlayer connecting conductor in the stacking direction defines a “via length” and a gap between the first and second interlayer connecting conductors defines a “line length.” The via length is longer than the line length.

### CROSS-REFERENCE TO RELATED APPLICATIONS

The present application is a bypass continuation of PCT/JP2024/017753, filed May 14, 2024, which claims priority to Japanese patent application JP 2023-138255, filed Aug. 28, 2023, the entire contents of each of which being incorporated herein by reference.

### TECHNICAL FIELD

The present disclosure relates to a multilayer bandpass filter.

### BACKGROUND ART

An example of a multilayer bandpass filter is described in Japanese Patent No. 6369638 (PTL 1).

The configuration described in PTL 1 has been employed as a method of ensuring an L value and achieving a good Q value of an efficient coil within a limited space by taking advantage of features of a process of a multilayer electronic component. Generally, a closed loop coil formed in a rectangular shape, i.e., a helical coil, can achieve a sufficiently good Q value to ensure a path for magnetic flux. Accordingly, it is considered preferable to set the length of each side to 1:1.

### CITATION LIST

### Patent Literature

PTL 1: Japanese Patent No. 6369638

### SUMMARY

### Technical Problems

As described in PTL 1, an LC resonator is known. The LC resonator includes a coil portion and a capacitance portion. The coil portion is formed by two interlayer connecting conductors and a conductor pattern connecting the interlayer connecting conductors together. The capacitance portion is formed by a part of a GND conductor pattern and a conductor pattern facing this part. In such an LC resonator, the interlayer connecting conductors have thus far been designed to be shorter than the conductor pattern connecting the interlayer connecting conductors together, due to actual product space constraints, a risk of structural defects resulting from an increased length of the interlayer connecting conductors, and to avoid increased costs.

The interlayer connecting conductors often have a circular cross-sectional shape, with low transmission loss. On the other hand, the conductor pattern connecting the interlayer connecting conductors together is formed by screen printing or the like, and therefore has either a rectangular cross-sectional shape with a thickness smaller than its dimension in the width direction or a rectangular cross-sectional shape with tapering ends, with relatively high transmission loss.

For the GND conductor pattern and the capacitance portion, not only the film thickness is reduced as a measure against structural defects, but also an additive such as glass, ceramic may be mixed to suppress shrinkage, and loss associated with a stray L component of the capacitance portion cannot be ignored.

Therefore, the present disclosure is directed to providing a multilayer bandpass filter capable of reducing loss and achieving a good Q value.

### Solutions to Problems

In order to realize the above and other features, a multilayer bandpass filter according to the present disclosure is a multilayer bandpass filter including at least one LC resonator inside a multilayer body formed by stacking a plurality of dielectric layers. The LC resonator has a loop shape arranged such that a winding axis is perpendicular to a stacking direction of the multilayer body inside the multilayer body. The LC resonator includes a capacitor conductor pattern, a line conductor pattern and a GND conductor pattern each disposed on a surface of a respective one of the plurality of dielectric layers, and includes a first interlayer connecting conductor and a second interlayer connecting conductor extending in the stacking direction. The capacitor conductor pattern and the line conductor pattern are connected to each other by the first interlayer connecting conductor. The line conductor pattern and the GND conductor pattern are connected to each other by the second interlayer connecting conductor. The LC resonator includes a capacitance portion in which at least a part of the capacitor conductor pattern and at least a part of the GND conductor pattern face each other to form a capacitance. The capacitor conductor pattern and the GND conductor pattern are disposed on different layers. With a length of the first interlayer connecting conductor in the stacking direction being defined as a “via length” and a length of a gap between the first interlayer connecting conductor and the second interlayer connecting conductor being defined as a “line length,” the via length is longer than the line length.

### Advantageous Effects

According to the present disclosure, since the via length is longer than the line length, electrical resistance can be kept low in one round of the loop of the LC resonator, which makes it possible to reduce loss and achieve a good Q value.

### BRIEF DESCRIPTION OF DRAWINGS

FIG. 1 is a perspective view of a multilayer bandpass filter in a first embodiment.

FIG. 2 is a perspective view showing only a structure formed by electrical conductors of an LC resonator included in the multilayer bandpass filter in the first embodiment.

FIG. 3 is a diagram showing the LC resonator included in the multilayer bandpass filter in the first embodiment, as seen in the direction of a winding axis.

FIG. 4 is a cross-sectional view taken along line IV-IV in FIG. 3 as seen in the direction of arrows.

FIG. 5 is a cross-sectional view taken along line V-V in FIG. 3 as seen in the direction of arrows.

FIG. 6 is a cross-sectional view of an example of a line conductor pattern included in the multilayer bandpass filter in the first embodiment.

FIG. 7 is a cross-sectional view of the multilayer bandpass filter in the first embodiment.

FIG. 8 is a cross-sectional view of a multilayer bandpass filter in a second embodiment.

FIG. 9 is a graph of results of a Q value determined by varying a line length L1 and a via length L2.

### DESCRIPTION OF EMBODIMENTS

The dimensional ratios shown in the drawings do not always faithfully represent the actual dimensional ratios, but may be exaggerated for the sake of explanation. In the following description, a reference to the concept “upper” or “lower” does not necessarily mean an absolute upper or lower position, but may mean a relatively upper or lower position in the postures shown in the drawings.

### First Embodiment

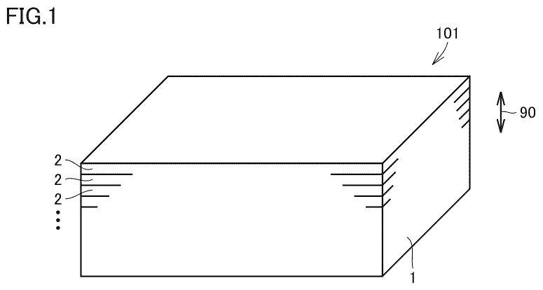

A multilayer bandpass filter in a first embodiment according to the present disclosure is described with reference to FIGS. 1 to 7. FIG. 1 shows an appearance of a multilayer bandpass filter 101 in the present embodiment. Multilayer bandpass filter 101 includes a multilayer body 1. Multilayer body 1 is fabricated by stacking a plurality of dielectric layers 2 to thereby integrate the layers into the multilayer body. In FIG. 1, multilayer bandpass filter 101 is illustrated in such a posture that a stacking direction 90 coincides with an up-down direction. FIG. 1 shows boundaries between dielectric layers 2, but in practice the boundaries may not always be visually discernible. FIG. 1 does not show any external terminals of multilayer bandpass filter 101, but in practice a plurality of external terminals are disposed on one of the surfaces of multilayer body 1. The plurality of external terminals may be disposed, for example, in the form of pad electrodes on the lower surface of multilayer body 1. In the present disclosure, the multilayer bandpass filter 101 may function as, or be integrated into, a radio frequency (RF) module. To facilitate understanding, certain structural elements described herein may be referred to by alternative industry-standard terminology. For example, the line conductor pattern 82 extending in a direction perpendicular to the stacking direction may be referred to as a “top conductor trace,” “lateral trace,” or “horizontal conductor pattern.” Similarly, the first and second interlayer connecting conductors 61, 62 extending in the stacking direction (or thickness direction) may be referred to as “vias,” “vertical interconnects,” or “vertical conductors.” The capacitance portion 3 may be referred to as a “capacitive structure,” formed by the facing capacitor conductor pattern 81 and GND conductor pattern 83, which may be respectively referred to as a “capacitor plate” and a “ground plate.” Furthermore, the term “stacking direction” corresponds to the “thickness direction” of the multilayer body, and the “longitudinal direction” of the line conductor pattern corresponds to the “lateral direction.”

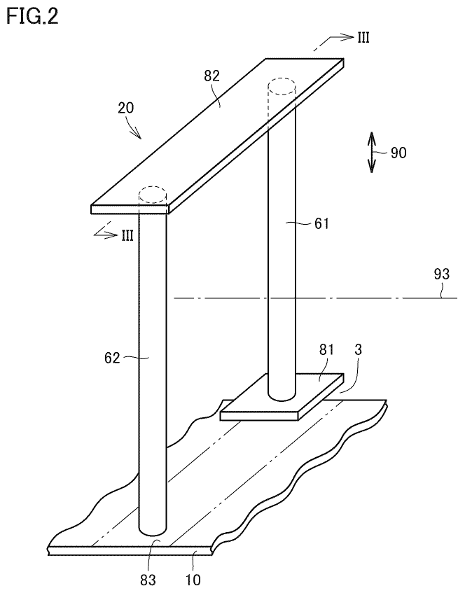

Multilayer bandpass filter 101 incorporates one or more LC resonators. FIG. 2 shows a perspective view of one LC resonator 20 incorporated in multilayer bandpass filter 101. FIG. 2 shows only a structure formed by electrical conductors, with dielectric layers 2 filling the space around LC resonator 20 having been removed. FIG. 2 shows only one LC resonator 20, but in practice a plurality of LC resonators 20 may be disposed side by side. A GND conductor film 10 is disposed at a lower position. A winding axis 93 is indicated by a dashed-and-dotted line in FIG. 2.

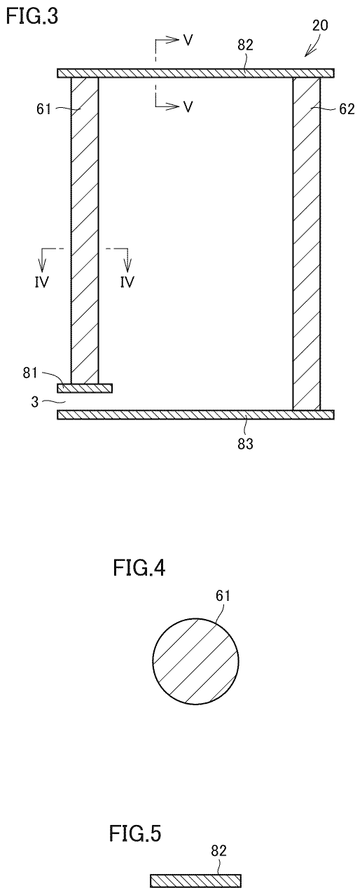

FIG. 3 shows LC resonator 20 as seen in the direction of winding axis 93. FIG. 4 shows a cross-sectional view taken along line IV-IV in FIG. 3 as seen in the direction of arrows. FIG. 5 shows a cross-sectional view taken along line V-V in FIG. 3 as seen in the direction of arrows.

Multilayer bandpass filter 101 is a multilayer bandpass filter including at least one LC resonator 20 inside multilayer body 1 formed by stacking the plurality of dielectric layers 2. LC resonator 20 has a loop shape arranged such that winding axis 93 is perpendicular to stacking direction 90 of multilayer body 1 inside multilayer body 1. LC resonator 20 includes a capacitor conductor pattern 81, a line conductor pattern 82 and a GND conductor pattern 83 each disposed on a surface of a respective one of the plurality of dielectric layers 2. LC resonator 20 includes a first interlayer connecting conductor 61 and a second interlayer connecting conductor 62 extending in stacking direction 90. In the present disclosure, the first and second interlayer connecting conductors 61, 62 constitute “vertical conductors” that extend in the stacking direction. Similarly, the line conductor pattern 82 extends in a direction perpendicular to the stacking direction and constitutes a “horizontal conductor pattern” connecting the vertical conductors. Capacitor conductor pattern 81 and line conductor pattern 82 are connected to each other by first interlayer connecting conductor 61. Line conductor pattern 82 and GND conductor pattern 83 are connected to each other by second interlayer connecting conductor 62. LC resonator 20 includes a capacitance portion 3 in which at least a part of capacitor conductor pattern 81 and at least a part of GND conductor pattern 83 face each other to form a capacitance. Capacitor conductor pattern 81 and GND conductor pattern 83 are disposed on different layers.

GND conductor pattern 83 may be a separate, independent conductor pattern, but is not limited to a separate, independent conductor pattern, and a part of extending GND conductor film 10 may be regarded as GND conductor pattern 83. In the example shown in FIG. 2, there is one large GND conductor film 10 common to the plurality of LC resonators 20, and several regions of this GND conductor film 10 serve as GND conductor patterns 83 for their respective LC resonators 20. An area corresponding to one GND conductor pattern 83 is virtually indicated by a dashed-and-double-dotted line in FIG. 2.

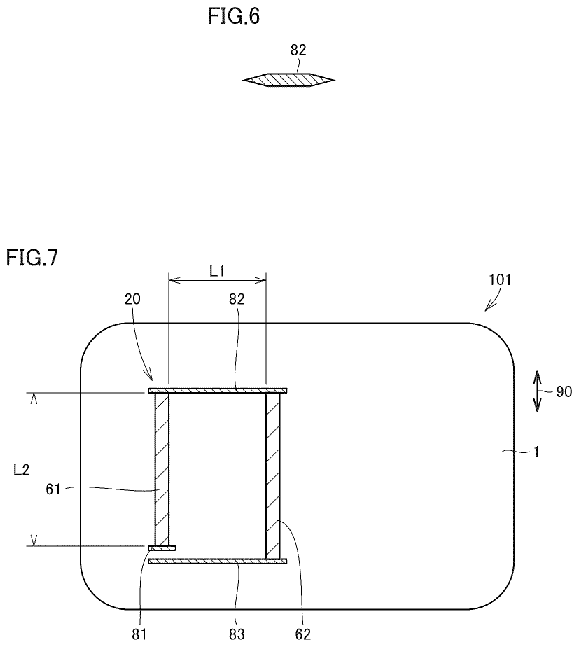

First interlayer connecting conductor 61 has a circular cross-sectional shape, as shown in FIG. 4. The same applies to the cross-sectional shape of second interlayer connecting conductor 62. Line conductor pattern 82 may have a rectangular cross-sectional shape, as shown in FIG. 5. Alternatively, line conductor pattern 82 may have a cross-sectional shape tapering toward opposite ends thereof, as shown in FIG. 6. The same applies to the cross-sectional shape of capacitor conductor pattern 81. The same applies to the cross-sectional shape of GND conductor pattern 83 in the case where GND conductor pattern 83 is a separate, independent conductor pattern.

With the length of first interlayer connecting conductor 61 in stacking direction 90 being defined as a “via length” and the length of a gap spanning between the facing inner surfaces of first interlayer connecting conductor 61 and second interlayer connecting conductor 62 being defined as a “line length,” the via length is longer than the line length. In the example shown in FIG. 7, the line length is denoted by L1 and the via length is denoted by L2. In this case, L2>L1. In the example shown in FIG. 7, LC resonator 20 is vertically long in shape, whereas multilayer body 1 is horizontally long in outer shape.

First interlayer connecting conductor 61 and second interlayer connecting conductor 62 having the circular cross-sectional shape as shown in FIG. 4 have a larger cross-sectional area and a longer periphery than line conductor pattern 82 having the cross-sectional shape as shown in FIG. 5 or 6, i.e., have an increased surface area. First interlayer connecting conductor 61 and second interlayer connecting conductor 62 are also less likely to be affected by edge effects because of their circular cross-sectional shape. As a result, electrical resistance can be kept low in first interlayer connecting conductor 61 and second interlayer connecting conductor 62 as compared to in line conductor pattern 82. In the present embodiment, since via length L2 is longer than line length L1, the electrical resistance can be kept low in one round of the loop of LC resonator 20, so that a good Q value can be achieved as a resonator. In other words, multilayer bandpass filter 101 in the present embodiment makes it possible to reduce loss and achieve a good Q value.

### Second Embodiment

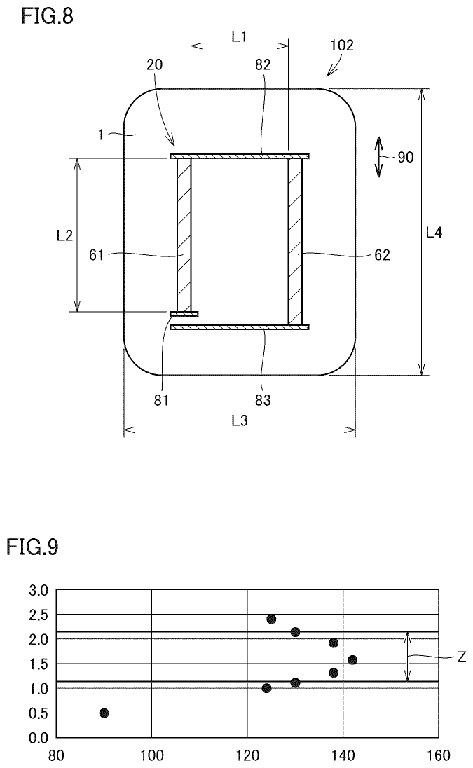

A multilayer bandpass filter in a second embodiment according to the present disclosure is described with reference to FIG. 8.

As shown in FIG. 8, in a multilayer bandpass filter 102, the length of multilayer body 1 in stacking direction 90 is longer than the length of multilayer body 1 along a longitudinal direction of line conductor pattern 82. The configuration is otherwise similar to that described in the first embodiment. That is, in multilayer bandpass filter 102, LC resonator 20 is vertically long in shape, and multilayer body 1 is also vertically long in outer shape.

In the present embodiment, since multilayer body 1 is vertically long in shape, the area required to mount this multilayer bandpass filter 102 can be reduced. Since multilayer body 1 and LC resonator 20 are both vertically long in shape, the characteristics per volume can be improved.

Using multilayer bandpass filter 101 described in the first embodiment as an example, it was examined how to set line length L1 and via length L2 shown in FIG. 7 to achieve particularly favorable results. As shown in Table 1, samples were simulated under conditions 1 to 8 by varying the values of L1 and L2, and a Q value was obtained from each of the simulations. Condition 1 is similar to a conventionally used condition. In condition 2, L1=L2, and LC resonator 20 has a substantially square shape.

TABLE 1

| | L1 | L2 | Cross-sectional area | | |
|---|---|---|---|---|---|
| | (μm) | (μm) | (μm²) | Q value | L2/L1 |
| Condition 1 | 800 | 400 | 320000 | 90 | 0.5 |
| Condition 2 | 475 | 475 | 225625 | 124 | 1.0 |
| Condition 3 | 450 | 500 | 225000 | 130 | 1.1 |
| Condition 4 | 400 | 525 | 210000 | 138 | 1.3 |
| Condition 5 | 350 | 550 | 192500 | 142 | 1.6 |
| Condition 6 | 300 | 575 | 172500 | 138 | 1.9 |
| Condition 7 | 275 | 587.5 | 161562.5 | 130 | 2.1 |
| Condition 8 | 250 | 600 | 150000 | 125 | 2.4 |

FIG. 9 shows, in graph form, results of the Q value determined under conditions 1 to 8, respectively. The vertical axis represents L2/L1 and the horizontal axis represents the Q value in FIG. 9. A higher Q value is better. As shown in FIG. 9, the Q value is particularly high in an area Z. This area Z corresponds to a range where L2/L1 is 1.1 or more and 2.1 or less. As can be seen therein, when a ratio of the via length L2 to the line length L1 is between 1.1 and 2.1, the trade-off between the resistance of the horizontal conductor pattern and the inductance of the loop may be optimized. As illustrated in FIG. 9, ratios outside this range result in a sharp decline in the Q value, indicating that this specific geometric relationship achieves the high-Q characteristics of the LC resonator 20.

From the foregoing, it is preferable that the value determined by dividing via length L2 by line length L1 be 1.1 or more and 2.1 or less in the multilayer bandpass filter.

When forming capacitance portion 3, a non-metal additive may be added to at least one of capacitor conductor pattern 81 and GND conductor pattern 83 in order to suppress sintering. Examples of such a non-metal additive include a glass component and a ceramic component. A drawback of such sintering suppression is potential degradation of the Q value of a stray L component of capacitance portion 3. Reducing line length L1 can reduce the L component in capacitance portion 3, thereby improving the Q value of LC resonator 20. In capacitance portion 3, it is preferable that capacitor conductor pattern 81 and GND conductor pattern 83 each contain the non-metal additive. By employing this configuration, benefits of the improved Q value can be more typically enjoyed.

More than one of the above embodiments may be employed in an appropriate combination.

The above embodiments disclosed herein are illustrative and non-restrictive in every respect. The scope of the present invention is defined by the terms of the claims, and encompasses any modifications within the meaning and scope equivalent to the terms of the claims.

### APPENDIX

### Appendix 1

A multilayer bandpass filter including at least one LC resonator inside a multilayer body formed by stacking a plurality of dielectric layers, wherein
the LC resonator has a loop shape arranged such that a winding axis is perpendicular to a stacking direction of the multilayer body inside the multilayer body,
the LC resonator includes a capacitor conductor pattern, a line conductor pattern and a GND conductor pattern each disposed on a surface of a respective one of the plurality of dielectric layers, and includes a first interlayer connecting conductor and a second interlayer connecting conductor extending in the stacking direction,
the capacitor conductor pattern and the line conductor pattern are connected to each other by the first interlayer connecting conductor, and the line conductor pattern and the GND conductor pattern are connected to each other by the second interlayer connecting conductor,
the LC resonator includes a capacitance portion in which at least a part of the capacitor conductor pattern and at least a part of the GND conductor pattern face each other to form a capacitance,
the capacitor conductor pattern and the GND conductor pattern are disposed on different layers, and
with a length of the first interlayer connecting conductor in the stacking direction being defined as a “via length” and a length of a gap between the first interlayer connecting conductor and the second interlayer connecting conductor being defined as a “line length,” the via length is longer than the line length.

### Appendix 2

The multilayer bandpass filter according to Appendix 1, wherein
a value determined by dividing the via length by the line length is 1.1 or more and 2.1 or less.

### Appendix 3

The multilayer bandpass filter according to Appendix 1 or 2, wherein
in the capacitance portion, the capacitor conductor pattern and the GND conductor pattern each contain a non-metal additive.

### Appendix 4

The multilayer bandpass filter according to any one of Appendixes 1 to 3, wherein
a length of the multilayer body in the stacking direction is longer than a length of the multilayer body along a longitudinal direction of the line conductor pattern.

### REFERENCE SIGNS LIST

1 multilayer body; 2 dielectric layer; 3 capacitance portion; 10 GND conductor film; 20 LC resonator; 61 first interlayer connecting conductor; 62 second interlayer connecting conductor; 81 capacitor conductor pattern; 82 line conductor pattern; 83 GND conductor pattern; 90 stacking direction; 93 winding axis; 101, 102 multilayer bandpass filter.

1. A multilayer bandpass filter including at least one LC resonator inside a multilayer body formed by stacking a plurality of dielectric layers, wherein
the LC resonator has a loop shape arranged such that a winding axis is perpendicular to a stacking direction of the multilayer body within the multilayer body,
the LC resonator includes a capacitor conductor pattern, a line conductor pattern, and a GND conductor pattern each disposed on a surface of a respective one of the plurality of dielectric layers, and includes a first interlayer connecting conductor and a second interlayer connecting conductor extending in the stacking direction,
the capacitor conductor pattern and the line conductor pattern are connected to each other by the first interlayer connecting conductor, and the line conductor pattern and the GND conductor pattern are connected to each other by the second interlayer connecting conductor,
the LC resonator includes a capacitance portion in which at least a part of the capacitor conductor pattern and at least a part of the GND conductor pattern face each other to form a capacitance,
the capacitor conductor pattern and the GND conductor pattern are disposed on different layers, and
with a length of the first interlayer connecting conductor in the stacking direction being defined as a “via length” and a length of a gap between the first interlayer connecting conductor and the second interlayer connecting conductor being defined as a “line length,” the via length is longer than the line length.

2. The multilayer bandpass filter according to claim 1, wherein
a ratio of the via length to the line length is between 1.1 and 2.1, inclusive.

3. The multilayer bandpass filter according to claim 1, wherein
in the capacitance portion, the capacitor conductor pattern and the GND conductor pattern each contain a non-metal additive.

4. The multilayer bandpass filter according to claim 1, wherein
a length of the multilayer body in the stacking direction is longer than a length of the multilayer body along a longitudinal direction of the line conductor pattern.

5. The multilayer bandpass filter according to claim 1, wherein the line conductor pattern has a cross-sectional shape tapered toward opposite ends thereof.

6. The multilayer bandpass filter according to claim 1, wherein the first interlayer connecting conductor and the second interlayer connecting conductor each have a circular cross-section.

7. The multilayer bandpass filter according to claim 1, wherein a total dimension of the multilayer body in the stacking direction is greater than a total dimension of the multilayer body along a longitudinal direction of the line conductor pattern.

8. A multilayer electronic component comprising:
a multilayer body including a plurality of dielectric layers laminated in a stacking direction; and
a resonator circuit embedded within the multilayer body, the resonator circuit comprising:
a first vertical conductor and a second vertical conductor extending in the stacking direction; and
a horizontal conductor pattern connecting upper ends of the first and second vertical conductors;
wherein the first and second vertical conductors and the horizontal conductor pattern form a conductive loop having a winding axis perpendicular to the stacking direction;
wherein the first vertical conductor has a via length (L2) in the stacking direction;
wherein a gap between inner facing surfaces of the first and second vertical conductors defines a line length (L1); and
wherein the resonator circuit is configured such that the via length (L2) is greater than the line length (L1).

9. The multilayer electronic component according to claim 8, wherein the resonator circuit further comprises:
a capacitor pattern connected to a lower end of the first vertical conductor; and
a ground pattern connected to a lower end of the second vertical conductor;
wherein the capacitor pattern and the ground pattern vertically overlap to define a capacitance.

10. The multilayer electronic component according to claim 9, wherein the capacitor pattern and the ground pattern each contain a non-metal additive.

11. The multilayer electronic component according to claim 8, wherein
a ratio of L2:L1 is between 1.1 and 2.1, inclusive.

12. The multilayer electronic component according to claim 8, wherein the first and second vertical conductors each have a circular cross-section.

13. The multilayer electronic component according to claim 8, wherein the multilayer body defines a height in the stacking direction and a width in a direction parallel to the horizontal conductor pattern, and wherein the height is greater than the width.

14. A radio frequency module comprising:
a multilayer body; and
a bandpass filter circuit integrated within the multilayer body;
wherein the bandpass filter circuit includes an LC resonator loop defined by:
a top conductor trace extending in a lateral direction;
a first via and a second via extending in a thickness direction of the multilayer body from opposing ends of the top conductor trace; and
a capacitive structure connecting a bottom end of the first via and a bottom end of the second via;
wherein a length of the first via in the thickness direction is greater than a gap between facing surfaces of the first and second vias in the lateral direction.

15. The radio frequency module according to claim 14, wherein the capacitive structure includes a capacitor plate connected to the first via and a ground plate connected to the second via, wherein the capacitor plate and ground plate are disposed on different layers of the multilayer body.

16. The radio frequency module according to claim 14, wherein a ratio of the length of the first via to the gap is within a range of 1.1 to 2.1, inclusive.

17. The radio frequency module according to claim 14, wherein the bandpass filter circuit is configured such that an electrical resistance of the first via is lower than an electrical resistance of the top conductor trace.

18. The radio frequency module according to claim 14, wherein the LC resonator loop is oriented vertically such that a winding axis of the loop is perpendicular to the thickness direction.
